(19) United States
(12) Patent Application Publication
(10) Pub. No.: US 2024/0324394 A1
(43) Pub. Date: Sep. 26, 2024

(54) DISPLAY APPARATUS

(71) Applicant: Samsung Display Co., Ltd., Yongin-si (KR)

(72) Inventors: Gun Kim, Yongin-si (KR); Heekwon Lee, Yongin-si (KR); Kukbin Lim, Yongin-si (KR); Jiwon Han, Yongin-si (KR)

(21) Appl. No.: 18/529,920

(22) Filed: Dec. 5, 2023

(30) Foreign Application Priority Data
Mar. 24, 2023 (KR) 10-2023-0039073
Mar. 30, 2023 (KR) 10-2023-0042247

(51) Int. Cl. H10K 59/80

(52) U.S. Cl. CPC H10K 59/80

(57) ABSTRACT

A display apparatus includes a first substrate, a second substrate that extends from the first substrate, and that is bendable, a display layer above the first substrate, a first plate below the first substrate, a second plate below the first plate, a first adhesion layer between the first plate and the second plate, and defining a first adhesion opening, a display circuit board below the second plate, and fixed to the second substrate that is in a bent state, and a coupling portion for coupling the display circuit board to the second plate, and overlapping the first adhesion opening.

### CROSS-REFERENCE TO RELATED APPLICATIONS

This application claims priority to, and the benefit of, Korean Patent Applications Nos. 10-2023-0039073 and 10-2023-0042247, respectively filed on Mar. 24, 2023, and Mar. 30, 2023, in the Korean Intellectual Property Office, the disclosures of which are incorporated by reference herein in their entirety.

### BACKGROUND

### 1. Field

One or more embodiments relate to a display apparatus.

### 2. Description of the Related Art

Mobile electronic devices have become widely used. As mobile electronic devices, tablet personal computers (PCs) have recently become broadly used, in addition to small electronic devices, such as mobile phones.

Such mobile electronic devices include display apparatuses to provide a user with visual information, such as an image or a video, to support various functions. Recently, with the miniaturization of various components for driving a display apparatus, the importance of the display apparatus for an electronic device has continually increased, and a structure whereby a flat display apparatus may be bent to have an angle (e.g., predetermined angle) has been developed.

### SUMMARY

One or more embodiments include a display apparatus having a structure for reducing or preventing transferal of an external force applied to a display circuit board to a first plate.

However, the above aspect is only an example, and the aspect to be solved by the disclosure is not limited thereto.

Additional aspects will be set forth in part in the description that follows and, in part, will be apparent from the description, or may be learned by practice of the presented embodiments of the disclosure.

According to one or more embodiments, a display apparatus includes a first substrate, a second substrate that extends from the first substrate, and that is bendable, a display layer above the first substrate, a first plate below the first substrate, a second plate below the first plate, a first adhesion layer between the first plate and the second plate, and defining a first adhesion opening, a display circuit board below the second plate, and fixed to the second substrate that is in a bent state, and a coupling portion for coupling the display circuit board to the second plate, and overlapping the first adhesion opening.

The first adhesion opening may include a 1-1^{st} adhesion opening defined in the coupling portion, and a 1-2^{nd} adhesion opening extending to an edge of the coupling portion from the 1-1^{st} adhesion opening.

The 1-2^{nd} adhesion opening may include a 1-21^{st} adhesion opening and a 1-22^{nd} adhesion opening spaced apart from each other.

The 1-1^{st} adhesion opening may be between the 1-21^{st} adhesion opening and the 1-22^{nd} adhesion opening.

A first via-hole connected to the first adhesion opening may be defined in the second plate.

The first via-hole may be connected to the coupling portion.

The first via-hole may include a 1-1^{st} via-hole and a 1-2^{nd} via-hole spaced apart from each other.

A size of the first adhesion opening may be the same as, or greater than, a size of the coupling portion in plan view.

The second substrate may contact the second plate.

The display apparatus may further include a support member in the first adhesion opening, and fixed to the first plate.

According to one or more embodiments, a display apparatus including a folding area that is foldable includes a substrate, a first plate below the substrate, a second plate below the first plate, a first adhesion layer between the first plate and the second plate, and defining a first adhesion opening, a display circuit board below the second plate, and a coupling portion for coupling the display circuit board to the second plate, and overlapping the first adhesion opening, wherein the display apparatus is foldable in a folding area.

The second plate may include a 2-1^{st} plate and a 2-2^{nd} plate with the folding area therebetween in plan view, wherein the coupling portion fixes the display circuit board to the 2-2^{nd} plate.

The first adhesion opening may include a 1-1^{st} adhesion opening in the coupling portion, and a 1-2^{nd} adhesion opening extending to an exterior of the coupling portion form the 1-1^{st} adhesion opening.

The 1-2^{nd} adhesion opening may include a 1-21^{st} adhesion opening and a 1-22^{nd} adhesion opening spaced apart from each other.

The 1-1^{st} adhesion opening may be between the 1-21^{st} adhesion opening and the 1-22^{nd} adhesion opening.

A first via-hole connected to the first adhesion opening may be defined by the second plate.

The first via-hole may be connected to the coupling portion.

The first via-hole may include a 1-1^{st} via-hole and a 1-2^{nd} via-hole spaced apart from each other.

A size of the first adhesion opening may be the same as, or greater than, a size of the coupling portion in plan view.

The display apparatus may further include an elastic member below the first plate and overlapping the folding area.

### BRIEF DESCRIPTION OF THE DRAWINGS

The above and other aspects of embodiments of the disclosure will be more apparent from the following description taken in conjunction with the accompanying drawings, in which:

FIG. 1 is a schematic perspective view of a display apparatus according to one or more embodiments;

FIG. 2 is a schematic plan view of a portion of a display apparatus according to one or more embodiments;

FIG. 3 is a schematic cross-sectional view of a display apparatus according to one or more embodiments;

FIG. 4 is a rear view of a portion of a display apparatus according to one or more embodiments;

FIG. 5 is a schematic cross-sectional view of a display panel according to one or more embodiments;

FIG. 6 is an equivalent circuit diagram of any one pixel of a display panel according to one or more embodiments;

FIG. 7 is a schematic cross-sectional view of a display apparatus according to one or more other embodiments; and

FIG. 8 is a rear view of a portion of a display apparatus according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined or combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

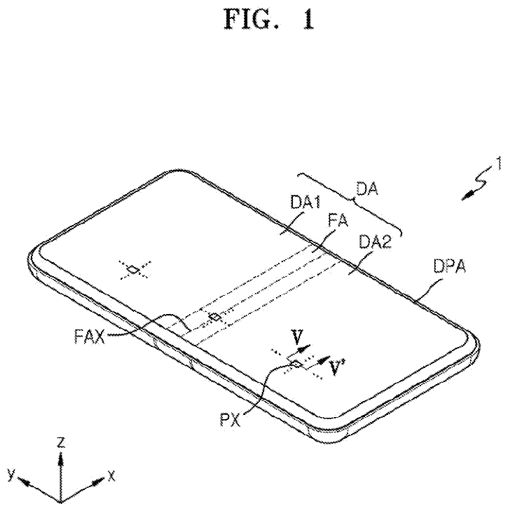

FIG. 1 schematic perspective view of a display apparatus 1 according to one or more embodiments.

Referring to FIG. 1, the display apparatus 1 may include an apparatus for displaying a video and a static image, and may be used as display screens not only of portable electronic apparatuses, such as a mobile phone, a smartphone, a tablet personal computer (PC), a mobile communication terminal, an electronic notebook, an electronic book, a portable multimedia player (PMP), a navigation device, and a ultra-mobile PC (UMPC), but also of various products, such as a television, a notebook computer, a monitor, an advertising board, and an Internet of things (IoT) device.

Also, the display apparatus 1 may be used in wearable devices, such as a smart watch, a watch phone, a glasses-type display, and a head-mounted display (HMD). Also, the display apparatus 1 may be used as, for example, a center information display (CID) on a gauge of a vehicle or a center fascia or a dashboard of the vehicle, a room mirror display substituting a side-view mirror of a vehicle, or a display located on a rear surface of a front seat, as an entertainment device for a backseat of a vehicle. FIG. 1 illustrates that the display apparatus 1 is used as a smartphone, for convenience of explanation.

The display apparatus 1 may include a display area DA and a peripheral area DPA outside the display area DA. Also, the display area DA may include a folding area FA that is foldable, and may further include a first display area DA1 and a second display area DA2 that are apart from each other with the folding area FA therebetween. The peripheral area DPA may be a type of non-display area where display elements are not arranged.

According to one or more embodiments, the display area DA may display an image. In detail, pixels PX may be arranged in the display area DA. Thus, the display apparatus 1 may provide an image by using the pixels PX arranged in the display area DA.

In this specification, the expression “upper” may indicate a +z-axis direction with respect to the display apparatus 1, and the expression “lower” may indicate a −z-axis direction with respect to the display apparatus 1.

The display apparatus 1 may have a rectangular shape in plan view. For example, the display apparatus 1 may have a rectangular planar shape having a long side in a first direction (e.g., a y-axis direction) and a short side in a second direction (e.g., an x-axis direction). A corner at which the long side in the first direction (for example, the y-axis direction) and the short side in the second direction (for example, the x-axis direction) meet each other may be curved to have a curvature (e.g., predetermined curvature) or may be right-angled. A planar shape of the display apparatus 1 is not limited to the rectangular planar shape and may include other shapes, such as a polygonal shape, an oval shape, or an amorphous shape.

The display apparatus 1 as described above may be provided to have various shapes. According to one or more embodiments, the display apparatus 1 may be provided to have a non-changeable shape. According to one or more embodiments, the display apparatus 1 may be provided to have a shape including at least one hinged portion. In this case, the display apparatus 1 may have an in-folding shape whereby the display area DA is folded to face each other when the display apparatus 1 is hinged or may have an out-folding shape whereby the display area DA is exposed to the outside when the display apparatus 1 is hinged. Hereinafter, for convenience of explanation, a case in which the display apparatus 1 has an in-folding shape is mainly described in detail.

In this case, the display apparatus 1 may be hinged with respect to a folding axis FAX. In this case, when the display apparatus 1 is hinged with respect to the folding axis FAX, a size of the display area DA may be reduced, and when the display apparatus 1 is completely unfolded, the display area DA may form a flat surface to display an image, thereby realizing a large screen.

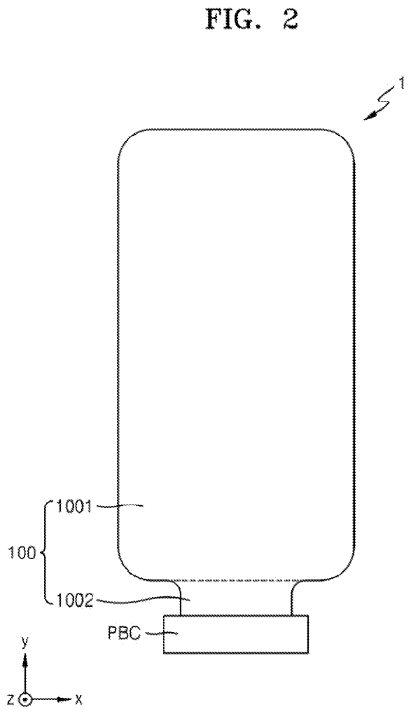

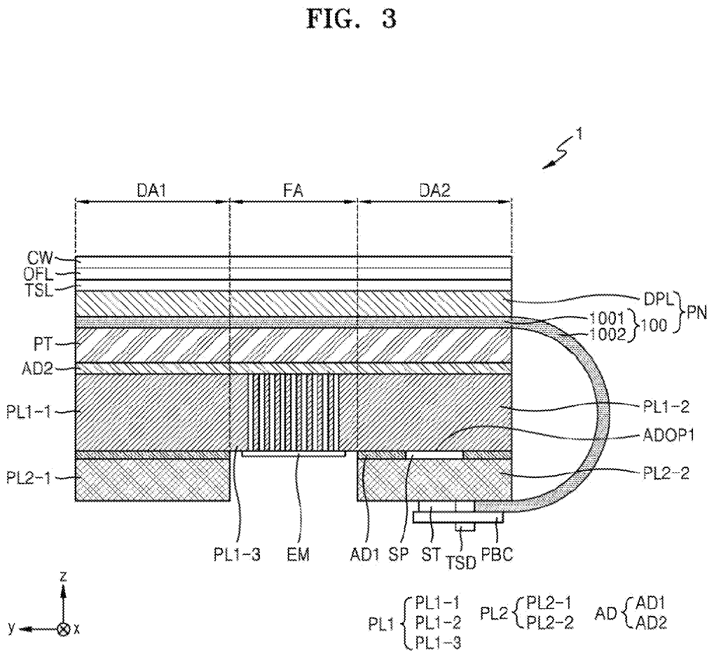

FIG. 2 is a schematic plan view showing a portion of the display apparatus 1 according to one or more embodiments, and FIG. 3 is schematic cross-sectional view of the display apparatus 1 according to one or more embodiments.

In detail, FIG. 2 illustrates only a substrate 100 and a display circuit board PBC, while a second substrate 1002 is being unfolded, for convenience of explanation.

Referring to FIGS. 2 and 3, the display apparatus 1 may include a display panel PN, a touch screen layer TSL, an optical functional layer OFL, a cover window CW, a first plate PL1, a second plate PL2, an adhesion layer AD, a panel protection member PT, the display circuit board PBC, a coupling portion ST, a support member SP, and an elastic member EM.

The display panel PN may include the substrate 100 and a display layer DPL.

The substrate 100 may include an insulating material, such as glass, quartz, and polymer resins. The substrate 100 may include a rigid substrate or a flexible substrate, which may be bent, folded, rolled, etc. For example, the substrate 100 may include polymer resins, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a layered structure including a layer including the polymer resins described above and an inorganic layer. For example, the substrate 100 may include two layers including the polymer resins described above and an inorganic barrier layer arranged between the two layers.

The substrate 100 may include a first substrate 1001 and the second substrate 1002 extending from the first substrate 1001. The second substrate 1002 may be bendable. The first substrate 1001 and the second substrate 1002 may include the same material as each other. For example, the first substrate 1001 and the second substrate 1002 may be integrally formed with each other. However, it is only an example, and the second substrate 1002 may include a flexible film, which is different from a material of the first substrate 1001, and may be connected to the first substrate 1001.

The display layer DPL may be arranged on the first substrate 1001. The display layer DPL may include pixels and may be a layer displaying an image. The display layer DPL may include a circuit layer including thin-film transistors, a display element layer in which display elements are arranged, and an encapsulation member for encapsulating the display element layer.

The touch screen layer TSL may be arranged on the display layer DPL. The touch screen layer TSL may include touch electrodes, and may be a layer for sensing a user's touch. The touch screen layer TSL may be directly formed on the encapsulation member of the display layer DPL. Alternatively, the touch screen layer TSL may be separately formed, and then, may be coupled to the encapsulation member of the display layer DPL through the adhesion layer AD, such as an optically clear adhesive (OCA).

The optical functional layer OFL may be arranged on the touch screen layer TSL. The optical functional layer OFL may include a reflection prevention layer (e.g., a reflection reduction layer). The reflection prevention layer may reduce reflectivity of light (external light) incident toward the display apparatus 1 from the outside.

According to some embodiments, the reflection prevention layer may include a polarization film. The polarization film may include a linear polarization plate and a phase delay film, such as a quarter-wave (N4) plate. The phase delay film may be arranged on the touch screen layer TSL, and the linear polarization plate may be arranged on the phase delay film.

According to some embodiments, the reflection prevention layer may include a filter layer including a black matrix and color filters. The color filters may be arranged by considering a color of light emitted from each of pixels in the display apparatus 1. For example, the filter layer may include a red color filter, a green color filter, or a blue color filter.

According to some embodiments, the reflection prevention layer may include a destructive interference structure. The destructive interference structure may include a first reflective layer and a second reflective layer located on different layers from each other. First reflective light and second reflective light reflected from the first reflective layer and the second reflective layer, respectively, may destructively interfere, and thus, the reflectivity of external light may be decreased.

The cover window CW may be arranged on the optical functional layer OFL. The cover window CW may be coupled to the optical functional layer OFL by a transparent adhesive member, such as an OCA.

The first plate PL1 may be arranged below the first substrate 1001. The first plate PL1 may include a 1-1^{st} plate PL1-1 corresponding to the first display area DA1, a 1-2^{nd} plate PL1-2 corresponding to the second display area DA2, and a 1-3^{rd} plate PL1-3 corresponding to the folding area FA.

The 1-1^{st} plate PL1-1, the 1-2^{nd} plate PL1-2, and the 1-3^{rd} plate PL1-3 may be integrally formed with one another. The 1-1^{st} plate PL1-1, the 1-2^{nd} plate PL1-2, and the 1-3^{rd} plate PL1-3 may include the same material as one another. The first plate PL1 may include a metal material.

The 1-3^{rd} plate PL1-3 may include a folding structure. The folding structure of the 1-3^{rd} plate PL1-3 may include a plurality of holes penetrating the 1-3^{rd} plate PL1-3 or a plurality of grooves recessed from a side of the 1-3^{rd} plate PL1-3. Due to the folding structure of the 1-3^{rd} plate PL1-3, the 1-3^{rd} plate PL1-3 may be relatively more easily folded.

The second plate PL2 may be arranged below the first plate PL1. The second plate PL2 may be separately arranged with respect to the folding area FA (e.g., may have portions on respective sides of the folding area FA). The second plate PL2 may at least partially overlap the first display area DA1 and the second display area DA2. For example, the second plate PL2 may include a 2-1^{st} plate PL2-1 and a 2-2^{nd} plate PL2-2. The 2-1^{st} plate PL2-1 may be arranged below the 1-1^{st} plate PL1-1, and the 2-2^{nd} plate PL2-2 may be arranged below the 1-2^{nd} plate PL1-2. That is, the 2-2^{nd} plate PL2-2 may be arranged to be spaced apart from the 2-1^{st} plate PL2-1 with the folding area FA therebetween (e.g., in plan view). The second plate PL2 may include a metal material. The second plate PL2 may absorb external shocks to protect the display panel PN.

The panel protection member PT may be arranged between the first substrate 1001 and the first plate PL1. The panel protection member PT may support and protect the display panel PN. The panel protection member PT may include PET or Pl.

The adhesion layer AD may include a PSA. The adhesion layer AD may include a first adhesion layer AD1 and a second adhesion layer AD2. The first adhesion layer AD1 may be arranged between the first plate PL1 and the second plate PL2. The first adhesion layer AD1 may be separately arranged with respect to the folding area FA. The first adhesion layer AD1 may be arranged between the 1-1^{st} plate PL1-1 and the 2-1^{st} plate PL2-1, and between the 1-2^{nd} plate PL1-2 and the 2-2^{nd} plate PL2-2. The first adhesion layer AD1 may fix the first plate PL1 and the second plate PL2. The second adhesion layer AD2 may be arranged between the panel protection member PT and the first plate PL1. The second adhesion layer AD2 may fix the panel protection member PT and the first plate PL1.

The display circuit board PBC may be arranged below the second plate PL2. For example, the display circuit board PBC may be arranged below the 2-2^{nd} plate PL2-2. The display circuit board PBC may include a flexible printed circuit board (FPCB), which is bendable, may include a rigid printed circuit board (RPCB), which is rigid and not easily bendable, or may include a complex printed circuit board including both of an FPCB and an RPCB. A power supply portion for supplying driving voltages for driving pixels of the display panel PN, and a scan driver may be additionally arranged on the display circuit board PBC.

A touch sensor driver TSD may be arranged on the display circuit board PBC. The touch sensor driver TSD may be formed as an integrated circuit. The touch sensor driver TSD may be coupled on the display circuit board PBC. The touch sensor driver TSD may be electrically connected to touch electrodes of the touch screen layer TSL through the display circuit board PBC.

The coupling portion ST may couple the display circuit board PBC to the second plate PL2. For example, the coupling portion ST may fix the display circuit board PBC to the 2-2^{nd} plate PL2-2. For example, the coupling portion ST may include a double-sided conductive tape.

The second substrate 1002 may be, in a bent state, fixed to the display circuit board PBC below the second plate PL2. A portion of the second substrate 1002 may be arranged between the display circuit board PBC and the second plate PL2. The second substrate 1002 may contact the display circuit board PBC and the second plate PL2. The second substrate 1002 may electrically connect the first substrate 1001 with the display circuit board PBC. As a result, the second substrate 1002 may be connected to the second plate PL2 by the display circuit board PBC and the coupling portion ST.

Because the second substrate 1002 is fixed to the display circuit board PBC in the bent state, the second substrate 1002 may have elastic resilience. An external force by the second substrate 1002 may be applied to the display circuit board PBC. The external force applied to the display circuit board PBC may be transferred to the coupling portion ST. That is, an external force may be applied to the coupling portion ST in a direction away from the first plate PL1 (for example, the −z-axis direction). The external force applied to the coupling portion ST may be transferred to the second plate PL2.

A first adhesion opening ADOP1 overlapping the coupling portion ST may be arranged in the first adhesion layer AD1. That is, the first adhesion layer AD1 may not be arranged between the first plate PL1 and the second plate PL2 overlapping the coupling portion ST.

When the first adhesion opening ADOP1 is not arranged in the first adhesion layer AD1, the external force transferred to the second plate PL2 may be transferred again to the first plate PL1 through the first adhesion layer AD1. Thus, an external force may be applied to a portion of the first plate PL1, the portion overlapping the coupling portion ST, in a direction toward the coupling portion ST (for example, the −z-axis direction). As a result, bending may occur to the first plate PL1 due to the external force. For example, the portion of the first plate PL1, which overlaps the coupling portion ST, may float in the direction toward the coupling portion ST (for example, the −z-axis direction). For example, as thicknesses of the first plate PL1 and the second plate PL2 decrease, a curvature of the second substrate 1002 may increase, and thus, an elastic resilience of the second substrate 1002 may increase, and the rigidity of the first plate PL1 and the second plate PL2 may decrease. Thus, this floating phenomenon may be intensified.

As the first adhesion opening ADOP1 is arranged in the first adhesion layer AD1, the external force applied to the second plate PL2 may not be transferred to the first plate PL1. That is, even when the second plate PL2 is bent due to the external force applied to the second plate PL2, the first plate PL1 may not be deformed, or may be minimally deformed. Thus, the floating phenomenon occurring in the first plate PL1 may be decreased, and the degree of flatness of the first plate PL1 may be improved. Accordingly, surface quality of the display apparatus 1 may be improved. That is, even when the thicknesses of the first plate PL1 and the second plate PL2 are decreased to decrease the thickness of the display apparatus 1, surface quality of the display apparatus 1 may be maintained.

The support member SP may be arranged in the first adhesion opening ADOP1, and may be fixed to the first plate PL1. The support member SP may support the first plate PL1, and may improve durability and surface quality of the display apparatus 1. The support member SP may not be fixed to the second plate PL2. Thus, the external force applied to the display circuit board PBC may not be transferred to the support member SP. The support member SP may include PET or PI.

For example, as illustrated in FIG. 3, a thickness of the support member SP may be the same as a thickness of the first adhesion layer AD1. Thus, the support member SP may contact the second plate PL2. However, this configuration is only an example, and (differently from what is illustrated in FIG. 3) the thickness of the support member SP may be less than the thickness of the first adhesion layer AD1. In this case, the support member SP may be spaced apart from the second plate PL2. However, the support member SP may not be arranged in the first adhesion opening ADOP1, and the first adhesion opening ADOP1 may be an empty space.

The elastic member EM may be arranged below the first plate PL1. The elastic member EM may be fixed below the 1-3^{rd} plate PL1-3. The elastic member EM may include a thermoplastic poly urethane (TPU) material. Due to the elastic member EM, durability of the first plate PL1 may be improved.

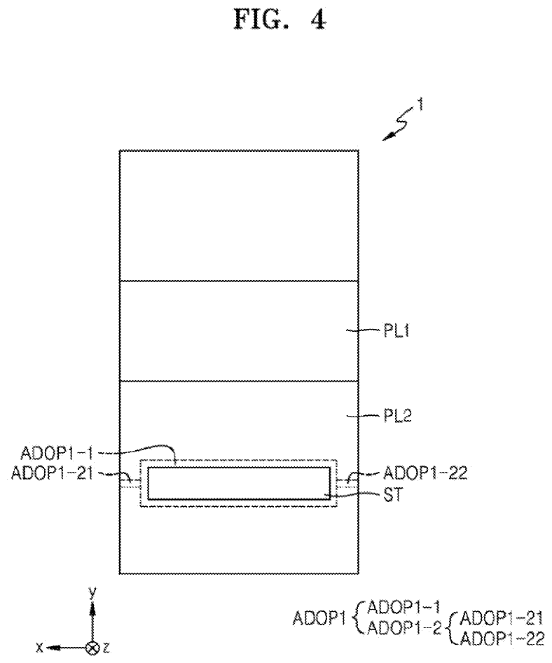

FIG. 4 is a rear view of a portion of a display apparatus according to one or more embodiments.

In detail, FIG. 4 illustrates only the first plate PL1, the second plate PL2, the first adhesion layer AD1, the first adhesion opening ADOP1, and the coupling portion ST, for convenience of explanation.

In FIG. 4, reference numerals that are the same as the reference numerals in FIG. 3 denote the same elements, and thus, their descriptions are not repeated.

Referring to FIGS. 3 and 4, the first adhesion opening ADOP1 may include a 1-1^{st} adhesion opening ADOP1-1 and a 1-2^{nd} adhesion opening ADOP1-2.

The 1-1^{st} adhesion opening ADOP1-1 may be arranged in the coupling portion ST to overlap the coupling portion ST. A size of the first adhesion opening ADOP1 may correspond to a size of the coupling portion ST. For example, a size of the 1-1^{st} adhesion opening ADOP1-1 may correspond to the size of the coupling portion ST. In a plan view, the size of the first adhesion opening ADOP1 may be the same as, or greater than, the size of the coupling portion ST. Thus, an external force transferred to the first plate PL1 from the second plate PL2 may be efficiently blocked. FIG. 4 illustrates that the 1-1^{st} adhesion opening ADOP1-1 has a square shape in plan view. However, it is only an example, and the shape of the 1-1^{st} adhesion opening ADOP1-1 may vary according to a shape of the display circuit board PBC.

The 1-2^{nd} adhesion opening ADOP1-2 may be connected to the outside through the 1-1^{st} adhesion opening ADOP1-1. That is, the 1-1^{st} adhesion opening ADOP1-1 may be open by the 1-2^{nd} adhesion opening ADOP1-2. In this structure, pressure of the 1-1^{st} adhesion opening ADOP1-1 may be the same as external pressure. Thus, the likelihood of a phenomenon in which an external force is applied to the first plate PL1 because the first adhesion opening ADOP1 has a pressure that is different from the external pressure due to an external force applied to the second plate PL2, may be reduced or prevented.

The 1-2^{nd} adhesion opening ADOP1-2 may include a 1-21^{st} adhesion opening ADOP1-21, and may include a 1-22^{nd} adhesion opening ADOP1-22 arranged to be spaced apart from the 1-21^{st} adhesion opening ADOP1-21. The 1-21^{st} adhesion opening ADOP1-21 and the 1-22^{nd} adhesion opening ADOP1-22 may be arranged with the 1-1^{st} adhesion opening ADOP1-1 therebetween. That is, in plan view, the first adhesion opening ADOP1 may haven a symmetrical shape. Thus, the first adhesion opening ADOP1 may efficiently reduce, absorb, or block the external force transferred to the first plate PL1.

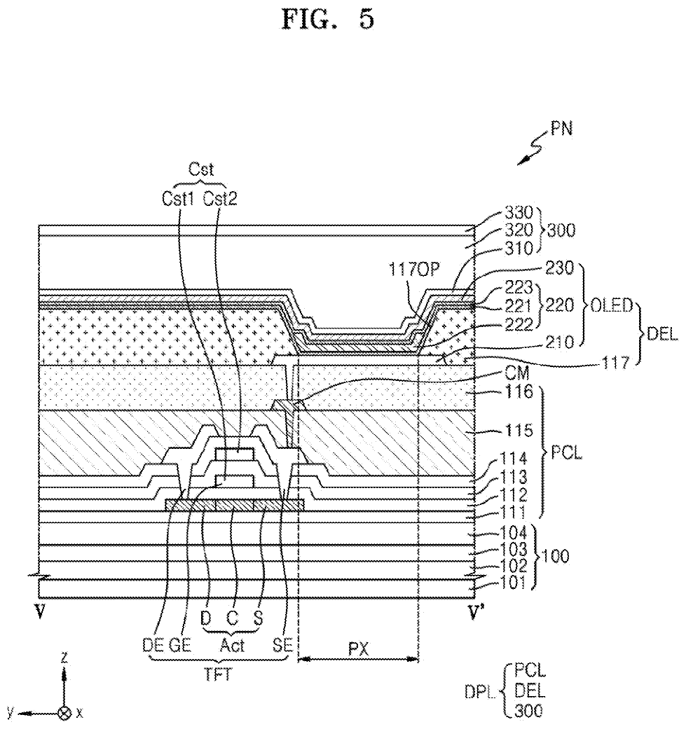

FIG. 5 is a schematic cross-sectional view of the display panel PN according to one or more embodiments and may correspond to the display panel PN taken along the line V-V′ of FIG. 1.

Referring to FIG. 5, the display panel PN may include the substrate 100 and the pixel layer DPL. In detail, the display layer DPL may include a structure in which a pixel circuit layer PCL, a display element layer DEL, and an encapsulation layer 300 are stacked.

The substrate 100 may have a layered structure including a base layer including polymer resins and an inorganic layer. For example, the substrate 100 may include a base layer including polymer resins and a barrier layer, which is an inorganic insulating layer. For example, the substrate 100 may include a first base layer 101, a first barrier layer 102, a second base layer 103, and a second barrier layer 104 that are sequentially stacked. The first base layer 101 and the second base layer 103 may include polyimide (PI), polyethersulfone (PES), polyarylate (PAR), polyetherimide (PEI), polyethylene naphthalate (PEN), polyethylene terephthalate (PET), polyphenylene sulfide (PPS), polycarbonate (PC), cellulose triacetate (TAC), or/and cellulose acetate propionate (CAP). The first barrier layer 102 and the second barrier layer 104 may include an inorganic insulating material, such as silicon oxide, silicon oxynitride, and/or silicon nitride. The substrate 100 may be flexible.

The pixel circuit layer PCL may be arranged on the substrate 100. FIG. 5 illustrates that the pixel circuit layer PCL includes a thin-film transistor TFT, and also includes a buffer layer 111, a first gate-insulating layer 112, a second gate-insulating layer 113, an interlayer insulating layer 114, a first planarization insulating layer 115, and a second planarization insulating layer 116 arranged below and/or above components of the thin-film transistor TFT.

The buffer layer 111 may reduce or block the penetration of impurities, moisture, or external materials from below the substrate 100 and may provide a planarized surface to the substrate 100. The buffer layer 111 may include an inorganic insulating material, such as silicon oxide, silicon oxynitride, and/or silicon nitride, and may include a single layer or layers including the inorganic insulating materials described above.

The thin-film transistor TFT on the buffer layer 111 may include a semiconductor layer Act, and the semiconductor layer Act may include polysilicon (poly-Si). Alternatively, the semiconductor layer Act may include amorphous silicon (a-Si), an oxide semiconductor, or an organic semiconductor. The semiconductor layer Act may include a channel area C, and a drain area D and a source area S at both sides of the channel area C. A gate electrode G may overlap the channel area C.

The gate electrode GE may include a low-resistance metal material. The gate electrode GE may include a conductive material including Mo, Al, Cu, Ti, etc. and may include layers or a single layer including the conductive materials described above.

The first gate-insulating layer 112 between the semiconductor layer Act and the gate electrode GE may include an inorganic insulating material, such as SiO₂, SiN_{X}, SiON, Al₂O₃, TiO₂, Ta₂O₅, HfO₂, ZnO_{X}, or the like. ZnOₓ may include ZnO and/or ZnO₂.

The second gate-insulating layer 113 may be provided to cover the gate electrode GE. Similar to the first gate-insulating layer 112, the second gate-insulating layer 113 may include an inorganic insulating material, such as SiO₂, SiN_{X}, SiON, Al₂O₃, TiO₂, Ta₂O₅, HfO₂, ZnO_{X}, or the like. ZnOₓ may include ZnO and/or ZnO₂.

An upper electrode Cst2 of a storage capacitor Cst may be arranged above the second gate-insulating layer 113. The upper electrode Cst2 may overlap the gate electrode GE therebelow. Here, the gate electrode GE and the upper electrode Cst2 overlapping each other with the second gate-insulating layer 113 therebetween may form the storage capacitor Cst. That is, the gate electrode GE may function as a lower electrode Cst1 of the storage capacitor Cst.

As described above, the storage capacitor Cst and the thin-film transistor TFT may be formed to overlap each other. According to some embodiments, the storage capacitor Cst may not be formed to overlap the thin-film transistor TFT.

The upper electrode Cst2 may include Al, Pt, Pd, Ag, Mg, Au, Ni, Nd, Ir, Cr, Ca, Mo, Ti, W, and/or Cu and may include a single layer or layers including the materials described above.

The interlayer insulating layer 114 may cover the upper electrode Cst2. The interlayer insulating layer 114 may include SiO₂, SiN_{X}, SiON, Al₂O₃, TiO₂, Ta₂O₅, HfO₂, ZnO_{X}, or the like. ZnOₓ may include ZnO and/or ZnO₂. The interlayer insulating layer 114 may include a single layer or layers including the inorganic insulating materials described above.

Each of a drain electrode DE and a source electrode SE may be arranged on the interlayer insulating layer 114. The drain electrode DE and the source electrode SE may be connected to the drain area D and the source area S, respectively, through contact holes formed in insulating layers below the drain electrode DE and the source electrode SE. The drain electrode DE and the source electrode SE may include a highly conductive material. The drain electrode DE and the source electrode SE may include a conductive material including Mo, Al, Cu, Ti, etc. and may include layers or a single layer including the materials described above. According to one or more embodiments, the drain electrode DE and the source electrode SE may have a layered structure of Ti/Al/Ti.

The first planarization insulating layer 115 may cover the drain electrode DE and the source electrode SE. The first planarization layer 115 may include an organic insulating material, such as a general-purpose polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

The second planarization insulating layer 116 may be arranged on the first planarization insulating layer 115. The second planarization insulating layer 116 may include the same material as the first planarization insulating layer 115, and may include an organic insulating material, such as a general-purpose polymer, such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

The display element layer DEL may be arranged on the pixel circuit layer PCL having the structure described above. The display element layer DEL may include an organic light-emitting diode OLED as a display element (that is, an emission device), and the organic light-emitting diode OLED may include a stack structure of a pixel electrode 210, an intermediate layer 220, and a common electrode 230. The organic light-emitting diode OLED may emit, for example, red, green, or may emit blue light or red, green, blue, or white light. The organic light-emitting diode OLED may emit light through an emission area, and the emission area may be defined as a pixel PX.

The pixel electrode 210 of the organic light-emitting diode OLED may be electrically connected to the thin-film transistor TFT via a contact metal CM arranged on the first planarization insulating layer 115 through contact holes formed in, or defined by, the second planarization insulating layer 116 and the first planarization insulating layer 115.

The pixel electrode 210 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to one or more other embodiments, the pixel electrode 210 may include a reflective layer including Ag, Mg, Al, Pt, Pd, Au, Ni, Nd, Ir, Cr, or a compound thereof. According to one or more other embodiments, the pixel electrode 210 may further include a layer including ITO, IZO, ZnO, or In₂O₃, above/below the reflective layer described above.

A bank layer 117 having, or defining, an opening 117OP exposing a central portion of the pixel electrode 210 may be arranged on the pixel electrode 210. The bank layer 117 may include an organic insulating material and/or an inorganic insulating material. The opening 117OP may define an emission area of light emitted from the organic light-emitting diode OLED. For example, a size/width of the opening 117OP may correspond to a size/width of the emission area. Thus, a size and/or a width of the pixel PX may be dependent on the size and/or the width of the opening 117OP of the bank layer 117.

The intermediate layer 220 may include an emission layer 222 formed to correspond to the pixel electrode 210. The emission layer 222 may include a high molecular-weight or a low molecular-weight organic material emitting light of a corresponding color. Alternatively, the emission layer 222 may include an inorganic emission material or quantum dots.

According to one or more embodiments, the intermediate layer 220 may include a first functional layer 221 and a second functional layer 223 arranged below and above the emission layer 222, respectively. The first functional layer 221 may include, for example, a hole transport layer (HTL), or an HTL and a hole injection layer (HIL). The second functional layer 223 may be arranged above the emission layer 222, and may include an electron transport layer (ETL) and/or an electron injection layer (EIL). The first functional layer 221 and/or the second functional layer 223 may be one or more common layers formed to entirely cover the substrate 100, like the common electrode 230 to be described below.

The common electrode 230 may be arranged on the pixel electrode 210 and may overlap the pixel electrode 210. The common electrode 230 may include a conductive material having a low work function. For example, the common electrode 230 may include a (semi-) transparent layer including Ag, Mg, Al, Pt, Pd, Au, Ni, Nd, Ir, Cr, Li, Ca, or an alloy thereof. Alternatively, the common electrode 230 may further include a layer, such as ITO, IZO, ZnO, or In₂O₃, on the (semi-) transparent layer including the materials described above. The common electrode 230 may be integrally formed to entirely cover the substrate 100.

The encapsulation layer 300 may be arranged on the display element layer DEL and may cover the display element layer DEL. The encapsulation layer 300 may include at least one inorganic encapsulation layer and/or at least one organic encapsulation layer. According to one or more embodiments, FIG. 5 illustrates that the encapsulation layer 300 may include a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material from among aluminum oxide, titanium oxide, tantalum oxide, hafnium oxide, ZnO, SiOₓ, SiNₓ, and/or SiON. The organic encapsulation layer 320 may include a polymer-based material. The polymer-based material may include acryl-based resins, epoxy-based resins, polyimide, polyethylene, etc. According to one or more embodiments, the organic encapsulation layer 320 may include acrylate. The organic encapsulation layer 320 may be formed by curing a monomer or coating a polymer. The organic encapsulation layer 320 may be transparent.

In one or more embodiments, a touch sensor layer may be arranged on the encapsulation layer 300, and an optical functional layer may be arranged on the touch sensor layer. The touch sensor layer may obtain coordinate information based on an external input, for example, a touch event. The optical functional layer may reduce a reflectivity of light (external light) incident toward a display apparatus from the outside and/or may improve a color purity of light emitted from the display apparatus. According to one or more embodiments, the optical functional layer may include a phase retarder and a polarizer. The phase retarder may include a film-type phase retarder or a liquid crystal coating-type phase retarder, and may include a λ/2 phase retarder and/or a λ/4 phase retarder. The polarizer may also include a film-type polarizer or a liquid crystal coating-type polarizer. The film-type polarizer may include an elongation-type synthetic resin film, and the liquid crystal coating-type polarizer may include liquid crystals arranged in a corresponding shape. The phase retarder and the polarizer may further include a protective film.

An adhesion member may be arranged between the touch electrode layer and the optical functional layer. The adhesion member is not limited to particular types, and may be implemented by using general members known in the art. The adhesion member may include a PSA.

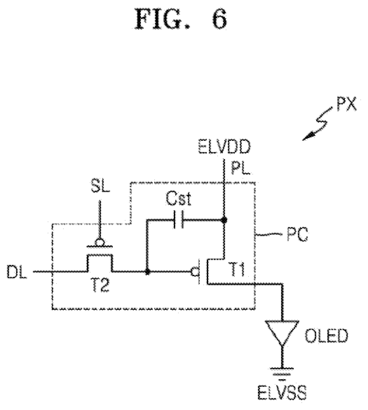

FIG. 6 is an equivalent circuit diagram of any one pixel of a display panel according to one or more embodiments.

Each pixel PX may include a pixel circuit PC and a display element connected to the pixel circuit PC, for example, an organic light-emitting diode OLED. The pixel circuit PC may include a first thin-film transistor T1, a second thin-film transistor T2, and a storage capacitor Cst. Each pixel PX may emit for example, red, green, blue, or white light through the organic light-emitting diode OLED.

The second thin film transistor T2 may include a switching thin film transistor, may be connected to a scan line SL and to a data line DL, and may be configured to transmit, to the first thin film transistor T1, a data voltage provided from the data line DL based on a switching voltage provided from the scan line SL.

The storage capacitor Cst may be connected to the second thin-film transistor T2 and to a driving voltage line PL, and may be configured to store a voltage corresponding to a difference between a voltage received from the second thin-film transistor T2 and a first power voltage ELVDD supplied to the driving voltage line PL.

The first thin-film transistor T1 may be a driving thin-film transistor, may be connected to the driving voltage line PL and to the storage capacitor Cst, and may be configured to control a driving current flowing from the driving voltage line PL through the organic light-emitting diode OLED according to a value of the voltage stored in the storage capacitor Cst. The organic light-emitting diode OLED may emit light having a corresponding brightness according to the driving current. An opposite electrode (for example, a cathode) of the organic light-emitting diode OLED may receive a second power voltage ELVSS.

FIG. 6 illustrates that the pixel circuit PC includes two thin-film transistors and one storage capacitor. However, the disclosure is not limited thereto. The number of thin-film transistors and the number of storage capacitors may be variously modified according to the design of the pixel circuit PC. For example, the pixel circuit PC may include two thin-film transistors, as described above, or three or more thin-film transistors.

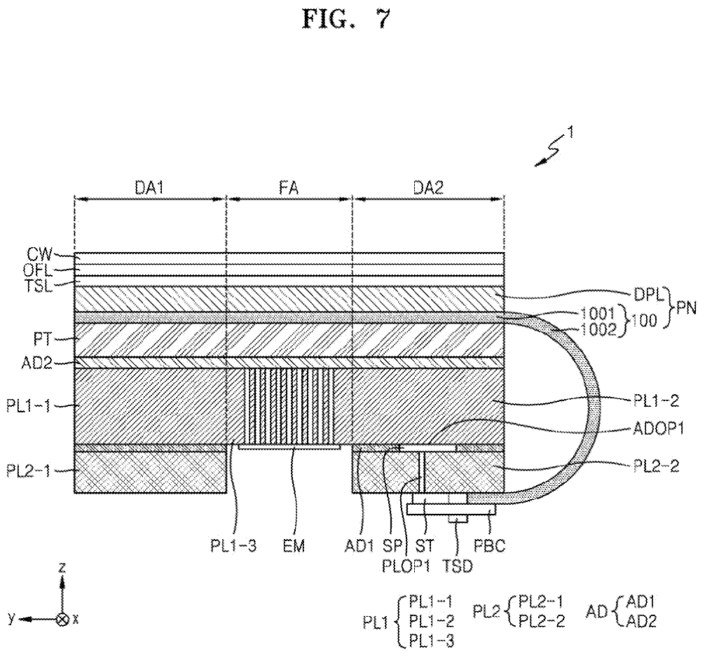

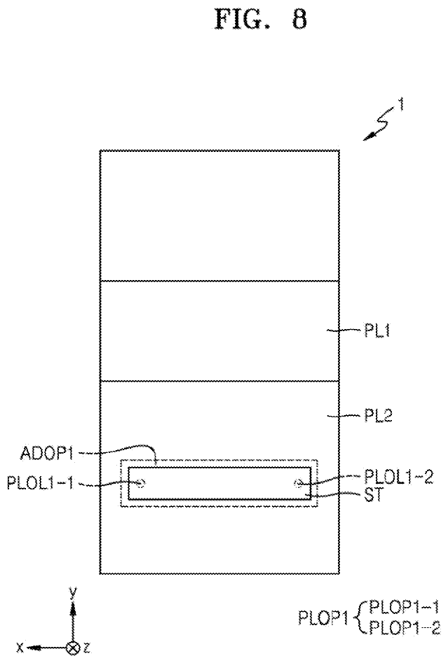

FIG. 7 is a schematic cross-sectional view of a display apparatus according to one or more other embodiments, and FIG. 8 is a rear view of a portion of the display apparatus according to one or more other embodiments.

In detail, FIG. 8 illustrates only the first plate PL1, the second plate PL2, the first adhesion layer AD1, the first adhesion opening ADOP1, and the coupling portion ST, for convenience of explanation.

In FIGS. 7 and 8, reference numerals that are the same as the reference numerals in FIGS. 3 and 4 denote the same elements, and thus, their descriptions are not repeated.

Referring to FIGS. 7 and 8, a first via-hole PLOP1 connected to the first adhesion opening ADOP1 may be arranged in the second plate PL2. The first via-hole PLOP1 may extend in a third direction (for example, a z-axis direction). The first via-hole PLOP1 may penetrate through the second plate PL2, and may connect the first adhesion opening ADOP1 with the coupling portion ST.

In a process of manufacturing a display apparatus, the second plate PL2 may be coupled to the first plate PL1 by using the first adhesion layer AD1, and then, the coupling portion ST may be coupled to the second plate PL2. In the process of coupling the second plate PL2 to the first plate PL1, compression may occur in the first adhesion opening ADOP1, and thus, the first adhesion opening ADOP1 may have lower pressure than the outside. However, due to the first via-hole PLOP1, the first adhesion opening ADOP1 and the outside may have substantially the same pressure as each other when the second plate PL2 is coupled to the first plate PL1. Thus, the phenomenon in which the external force is applied to the first plate PL1 due to a difference in pressure between the first adhesion opening ADOP1 and the outside caused by the compression, may be reduced or prevented.

The first via-hole PLOP1 may include a 1-1^{st} via-hole PLOP1-1, and may include a 1-2^{nd} via-hole PLOP1-2 arranged to be spaced apart from the 1-1^{st} via-hole PLOP1-1. The first via-hole PLOP1 may be provided in plural, and thus, the compression occurring in the first adhesion opening ADOP1 may be efficiently reduced. FIG. 8 illustrates that the first via-hole PLOP1 includes two first via-holes. However, it is only an example, and the number of first via-holes PLOP1 is not limited thereto.

According to the one or more of the above embodiments of the disclosure, a display apparatus may have improved surface quality and durability.

Effects of the one or more of the embodiments described above are not limited to the effects described above, and other effects that not are described may be clearly understood by one of ordinary skill in the art from the disclosure of the claims.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by those of ordinary skill in the art that various changes in form and details may be made therein without departing from the spirit and scope as defined by the following claims, with functional equivalents thereof to be included therein.

What is claimed is:

1. A display apparatus comprising:
a first substrate;
a second substrate that extends from the first substrate, and that is bendable;
a display layer above the first substrate;
a first plate below the first substrate;
a second plate below the first plate;
a first adhesion layer between the first plate and the second plate, and defining a first adhesion opening;
a display circuit board below the second plate, and fixed to the second substrate that is in a bent state; and
a coupling portion for coupling the display circuit board to the second plate, and overlapping the first adhesion opening.

2. The display apparatus of claim 1, wherein the first adhesion opening comprises:
a 1-1^{st} adhesion opening defined in the coupling portion; and
a 1-2^{nd} adhesion opening extending to an edge of the coupling portion from the 1-1^{st} adhesion opening.

3. The display apparatus of claim 2, wherein the 1-2^{nd} adhesion opening comprises a 1-21^{st} adhesion opening and a 1-22^{nd} adhesion opening spaced apart from each other.

4. The display apparatus of claim 3, wherein the 1-1^{st} adhesion opening is between the 1-21^{st} adhesion opening and the 1-22^{nd} adhesion opening.

5. The display apparatus of claim 1, wherein a first via-hole connected to the first adhesion opening is defined in the second plate.

6. The display apparatus of claim 5, wherein the first via-hole is connected to the coupling portion.

7. The display apparatus of claim 5, wherein the first via-hole comprises a 1-1^{st} via-hole and a 1-2^{nd} via-hole spaced apart from each other.

8. The display apparatus of claim 1, wherein a size of the first adhesion opening is the same as, or greater than, a size of the coupling portion in plan view.

9. The display apparatus of claim 1, wherein the second substrate contacts the second plate.

10. The display apparatus of claim 1, further comprising a support member in the first adhesion opening, and fixed to the first plate.

11. A display apparatus comprising:
a substrate;
a first plate below the substrate;
a second plate below the first plate;
a first adhesion layer between the first plate and the second plate, and defining a first adhesion opening;
a display circuit board below the second plate; and
a coupling portion for coupling the display circuit board to the second plate, and overlapping the first adhesion opening,
wherein the display apparatus is foldable in a folding area.

12. The display apparatus of claim 11, wherein the second plate comprises a 2-1^{st} plate and a 2-2^{nd} plate with the folding area therebetween in plan view, and
wherein the coupling portion fixes the display circuit board to the 2-2^{nd} plate.

13. The display apparatus of claim 11, wherein the first adhesion opening comprises a 1-1^{st} adhesion opening in the coupling portion, and a 1-2^{nd} adhesion opening extending to an exterior of the coupling portion form the 1-1^{st} adhesion opening.

14. The display apparatus of claim 13, wherein the 1-2^{nd} adhesion opening comprises a 1-21^{st} adhesion opening and a 1-22^{nd} adhesion opening spaced apart from each other.

15. The display apparatus of claim 14, wherein the 1-1^{st} adhesion opening is between the 1-21^{st} adhesion opening and the 1-22^{nd} adhesion opening.

16. The display apparatus of claim 11, wherein a first via-hole connected to the first adhesion opening is defined by the second plate.

17. The display apparatus of claim 16, wherein the first via-hole is connected to the coupling portion.

18. The display apparatus of claim 16, wherein the first via-hole comprises a 1-1^{st} via-hole and a 1-2^{nd} via-hole spaced apart from each other.

19. The display apparatus of claim 11, wherein a size of the first adhesion opening is the same as, or greater than, a size of the coupling portion in plan view.

20. The display apparatus of claim 11, further comprising an elastic member below the first plate and overlapping the folding area.
